(19) United States
(12) Patent Application Publication
(10) Pub. No.: US 2010/0086864 A1
(43) Pub. Date: Apr. 8, 2010

(54) METHOD OF POLISHING GLASS SUBSTRATE

(75) Inventors: Hiroshi KOJIMA, Tokyo (JP); Masabumi Ito, Tokyo (JP); Satoshi Takemiya, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: ASAHI GLASS COMPANY, LIMITED, Tokyo (JP)

(21) Appl. No.: 12/635,872

(22) Filed: Dec. 11, 2009

Related U.S. Application Data
(63) Continuation of application No. PCT/JP08/59100, filed on May 13, 2008.

(30) Foreign Application Priority Data
Jun. 13, 2007 (JP) 2007-156890

(51) Int. Cl. G03F 1/00

(52) U.S. Cl. 430/5

(57) ABSTRACT

The present invention is to provide a method of polishing a glass substrate required to have extremely high surface smoothness and surface accuracy like glass substrates for mask blanks. The invention relates to a method of polishing a glass substrate which comprises polishing the glass substrate with a polishing pad while supplying a polishing slurry comprising an abrasive material and water to the polishing pad, wherein the polishing slurry contains at least one member selected from the group consisting of pullulan and water-soluble alcohols which are polyvalent organic compounds having two or more OH groups. The slurry preferably has a pH adjusted to 0.5-4.

### TECHNICAL FIELD

The present invention relates to a method of polishing a glass substrate. More particularly, the invention relates to a polishing method suitable for glass substrates for mask blanks to be used in semiconductor device production steps.

### BACKGROUND ART

In semiconductor device production steps, an exposure tool for transferring a fine circuit pattern to a wafer to produce an integrated circuit has conventionally been used extensively. With the trend toward higher degrees of integration and function advancement in semiconductor integrated circuits, the scale down of integrated circuits proceeds in recent years. For precisely forming a circuit pattern image on a wafer surface, a glass substrate for a mask blank to be used as a photomask in an exposure tool is required to have a high degree of flatness and smoothness.

Under such technical circumstances, a lithographic technique employing EUV (extreme ultraviolet) light as a next-generation exposure light has attracted attention since it is considered to be applicable to the 45-nm and succeeding generations. The term EUV light means a light having a wavelength in the soft X-ray region or vacuum ultraviolet region, specifically a light having a wavelength of about 0.2-100 nm. At present, use of a lithographic light having a wavelength of 13.5 nm is being investigated. The exposure principle of this EUV lithography (hereinafter abbreviated to “EUVL”) is equal to that of conventional lithography in that a mask pattern is transferred with an optical projection system. However, a refractive optical system cannot be used because there is no material which is light-transmitting in the EUV light energy region, and a reflective optical system should be used (see patent document 1).

In patent document 2 is described a method of polishing a glass substrate for use as a photomask in such EUVL. In this polishing method, a polishing slurry which comprises colloidal silica having an average primary-particle diameter of 50 nm or smaller and water and has a pH regulated to 1-4 is used to polish a surface of a glass substrate comprising SiO₂ as the main component to obtain a glass substrate having a surface roughness Rms as determined with an atomic force microscope of 0.15 nm or lower.

In patent document 3, an abrasive material comprising fine oxide particles, pullulan, and water is described as an abrasive material which attains a high rate of polishing and is effective in inhibiting dishing or erosion when used for polishing a work surface in the production of a semiconductor integrated-circuit device. Namely, this abrasive material is useful for the production of a semiconductor integrated-circuit device in a process which comprises forming an insulating layer on a substrate, forming a trench pattern for wiring in the insulating layer, subsequently forming a barrier layer, thereafter filling the trenches with copper, and then removing the excess copper and barrier layer by a chemical mechanical polishing method until the surface of the insulating layer excluding the trenches is exposed to thereby make the surface flat and form a metallic wiring (damascene method). The abrasive material has the effect of inhibiting the occurrence of erosion in the metallic wiring part.

Patent Document 1: JP-T-2003-505891

Patent Document 2: JP-A-2006-35413

Patent Document 3: JP-A-2005-294798

### DISCLOSURE OF THE INVENTION

According to the polishing method described in patent document 2, the surface roughness Rms of a glass substrate can be reduced to 0.15 nm or lower by using the polishing slurry. In addition, the polishing slurry is effective in inhibiting the occurrence of concave defects, which have been regarded as difficult to diminish, whereby the surface properties of the glass substrate can be improved. However, that polishing slurry has a drawback that the colloidal silica, during polishing, readily aggregates or dries and is hence apt to cause concave defects. It has therefore been necessary to strictly control the polishing slurry so as to inhibit the occurrence of such concave defects. Furthermore, there have been problems, for example, that since the colloidal silica is in direct contact with the substrate during polishing, friction between these is enhanced and, hence, the colloidal silica is apt to cause concave defects in the same manner.

On the other hand, the abrasive material described in patent document 3 is intended to be used for polishing the side to be polished of a multilayer metallic wiring in the production of a semiconductor integrated-circuit device by preferentially polishing convex parts while inhibiting concave parts (metallic-wiring parts) from being preferentially polished, as stated above, to thereby inhibit the occurrence of dishing or erosion and make the surface flat. Consequently, this abrasive material is effective in the planarization polishing of the side to be polished of a multilayer metallic wiring. However, the polishing of a glass substrate having no multilayer metallic wiring is different from that polishing, and it is difficult to realize polishing which yields a glass substrate especially free from concave defects.

The invention has been achieved in view of the problems described above. An object of the invention is to provide a method of polishing a glass substrate required to have extremely high surface smoothness and flatness like glass substrates for mask blanks.

In order to solve the above-described problems, the present inventors diligently made investigations on polishing for obtaining a glass substrate usable as a mask blank in the optical system of an exposure tool for producing semiconductor devices of the 45-nm and succeeding generations. As a result, they have found that when pullulan or a water-soluble polyhydric alcohol having two or more OH groups is added to a polishing slurry, then glass substrate polishing is greatly improved. The invention has been thus completed.

The invention provides a method of polishing a glass substrate which comprises polishing the glass substrate with a polishing pad while supplying a polishing slurry comprising an abrasive material and water to the polishing pad, wherein the polishing slurry contains at least one member selected from the group consisting of pullulan and water-soluble alcohols which are polyvalent organic compounds having two or more OH groups.

It is especially preferred in the invention that the polishing slurry contains the alcohol(s). In this case, the content of the alcohols in the polishing slurry is preferably 0.02-20% by mass.

In the method of glass substrate polishing of the invention, the abrasive material is preferably fine particles of silica having an average primary-particle diameter of 80 nm or smaller. Especially preferred is colloidal silica. The polishing slurry preferably has a pH of 0.5-4.

When a glass substrate is polished by the method of glass substrate polishing of the invention, the surface of the glass substrate preferably has been preliminarily polished. The polishing pad preferably has a nap layer having a compressibility of 10% or higher and a compressive elastic modulus of 85% or higher.

According to the invention, the occurrence of concave defects can be diminished because the addition of pullulan or a water-soluble polyhydric alcohol having two or more OH groups to the polishing slurry is effective in preventing the abrasive material from aggregating or drying.

Furthermore, the abrasive material in the polishing slurry is surrounded by the pullulan or alcohol added and, hence, direct contact between the abrasive material and the glass substrate is relieved to reduce friction between these. This also is effective in diminishing the occurrence of concave defects. In addition, the pullulan or alcohol added protects the surface to be polished of the glass substrate and, hence, particles of the abrasive material and waste glass particles resulting from polishing are less apt to adhere to the surface being polished. Thus, the surface smoothness of the glass substrate can be improved.

According to the present invention as described above, a glass substrate can be polished to such an extent that gives a surface having few concave defects and a low surface roughness. Thus, a glass substrate having excellent surface smoothness can be obtained which is usable also in an exposure tool for producing semiconductor devices of the 45-nm and succeeding generations.

### BRIEF DESCRIPTION OF THE DRAWINGS

FIG. 1 is a schematic view of a glass substrate being polished with a polishing slurry according to the invention.

FIG. 2 is a diagrammatic sectional view illustrating a concave defect.

FIG. 3 is a front view of a preferred polishing suede pad for use in the invention.

The reference numerals used in the drawings denote the following, respectively.

1: Glass substrate

2: Fine abrasive particle

3: Additive

4: Surface to be polished

5: Concave defect

6: Supporting base

7: Nap layer

### BEST MODE FOR CARRYING OUT THE INVENTION

Embodiments of the invention are explained below. However, the invention should not be construed as being limited to the following embodiments. Embodiments which are in agreement with the spirit of the invention and produce the same effect are encompassed by the invention.

The glass to be polished as a glass substrate in the invention preferably is a low-expansion glass having a low coefficient of thermal expansion and reduced nonuniformity of the coefficient so as to obtain a glass substrate capable of conforming to the demand for higher degrees of integration and higher fineness in integrated circuits. Specifically, a low-expansion glass having a coefficient of thermal expansion at 20° C. or at 50-80° C. of −30 to 30 ppb/° C. is preferred, and an extremely-low-expansion glass having a coefficient of thermal expansion at 20° C. or at 50-80° C. of −10 to 10 ppb/° C. is especially preferred. So long as the glass substrate has such a low coefficient of thermal expansion, it sufficiently copes with temperature changes in semiconductor device production steps and can satisfactorily transfer a circuit pattern with high resolution.

As the low-expansion glass can be advantageously used a quartz glass comprising SiO₂ as the main component. Examples thereof include low-expansion glasses or low-expansion crystallized glasses, such as a synthetic quartz glass comprising SiO₂ as the main component and containing TiO₂, ULE (registered trademark; Corning Code 7972), and ZERODUR (registered trademark of Schott AG, Germany). Although the glass substrate is usually polished in the form of a rectangular plate, the shape thereof is not limited thereto.

The polishing slurry to be used in the invention preferably is a polishing slurry with which the surface to be polished of a glass substrate can be chemically and mechanically polished. This polishing slurry comprises an abrasive material and water and further contains at least one member selected from the group consisting of pullulan and water-soluble alcohols which are polyvalent organic compounds having two or more OH groups. It is preferred that the polishing slurry should further contain an acid. When this polishing slurry is used, the surface to be polished of a glass substrate can be polished while inhibiting the occurrence of concave defects. Thus, a flat and smooth polished surface can be obtained.

The abrasive material in the polishing slurry is fine abrasive particles which mechanically polish the surface to be polished of a glass substrate. Specifically, the abrasive material may be fine particles of an oxide. The oxide is preferably at least one member selected from the group consisting of silica, alumina, zirconium oxide (zirconia), titanium oxide (titania), and the like. Preferred of these is silica. Examples of the silica include fine silica particles, including colloidal silica and fumed silica, which are produced by various known methods. However, colloidal silica is preferred from the standpoint that a high-purity product having a uniform particle diameter can be obtained. The particle diameter and content of the abrasive material will be explained below using colloidal silica as an example. However, substantially the same explanation applies to other abrasive materials.

The average primary-particle diameter of the colloidal silica is preferably 80 nm or smaller, more preferably 50 nm or smaller, further preferably 30 nm or smaller. Although there is no lower limit on the average primary-particle diameter of the colloidal silica, the average primary-particle diameter is preferably 5 nm or larger, more preferably 10 nm or larger, from the standpoint of improving the efficiency of polishing. If the average primary-particle diameter of the colloidal silica exceeds 80 nm, the colloidal silica having such a large particle diameter causes concave defects (pits) and scratches to the glass substrate. There is hence a possibility that the polishing cannot give a polished surface which has few concave defects and a desired surface roughness. From the standpoint of strictly controlling particle diameter, it is desirable that the colloidal silica contains secondary particles formed by the aggregation of primary particles as less as possible. When the colloidal silica includes secondary particles, the average particle diameter of these particles is preferably 70 nm or smaller. In the invention, the particle diameter of colloidal silica is a diameter obtained through an examination of images having a magnification of (15−105)×10³ with an SEM (scanning electron microscope).

The content of colloidal silica in the polishing slurry is preferably 10-30% by mass, more preferably 18-25% by mass. An optimal content within this range is determined while taking account of polishing rate, the uniformity and dispersibility of the colloidal silica, etc. Colloidal silica contents lower than 10% by mass are undesirable because the efficiency of polishing decreases and this results in a prolonged polishing time. Especially when colloidal silica having a small average primary-particle diameter is employed as an abrasive material as in the invention, colloidal silica contents lower than 10% by mass result in an impaired polishing efficiency and this may make economical polishing impossible. On the other hand, if the content of colloidal silica exceeds 30% by mass, the amount of the colloidal silica to be used increases. Consequently, such too high contents of colloidal silica are undesirable from the standpoints of profitability, washability, etc.

The invention is characterized in that the polishing slurry contains at least one member selected from the group consisting of pullulan and water-soluble alcohols which are polyvalent organic compounds having two or more OH groups (hereinafter referred to simply as alcohols). Although the slurry generally contains either one of pullulan and the alcohol, it may contain two or more members selected from pullulan and the alcohols. In the following description, either or both of pullulan and the alcohols are referred to as additive for convenience.

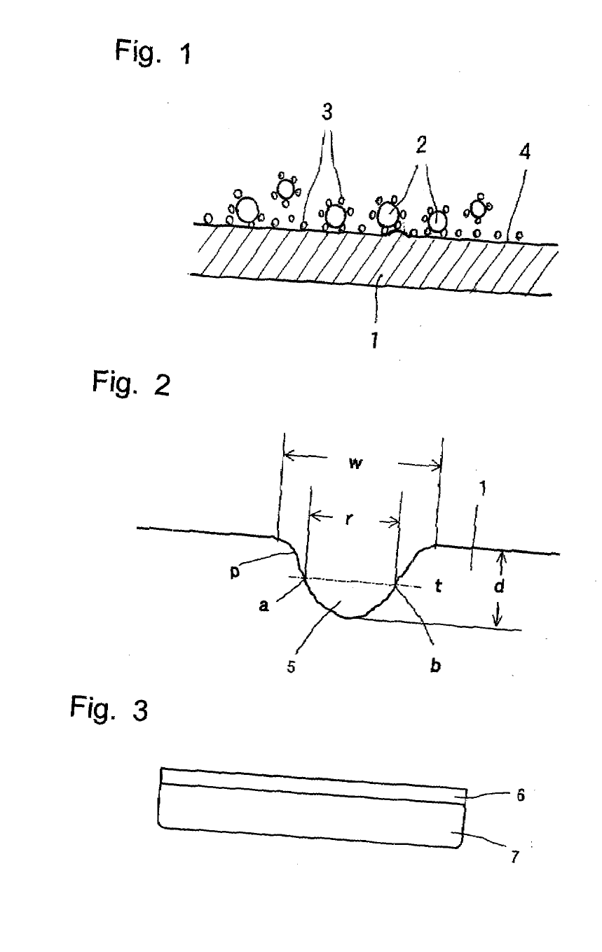

When the polishing slurry contains the additive, the additive 3 not only covers the surface of fine abrasive particles 2 but also covers the surface to be polished 4 of a glass substrate 1 to protect the surface, as shown in FIG. 1. As a result, the additive produces the following effects. Covering fine particles of the abrasive material with the additive prevents the abrasive material from aggregating or drying and hence it has improved dispersion stability. Because of this, the polishing slurry can always keep a uniformity and satisfactory flowability. Consequently, the occurrence of concave defects can be inhibited or reduced. Furthermore, the covering of the fine abrasive particles with the additive reduces friction between the fine abrasive particles and the glass substrate during polishing, whereby the fine abrasive particles can be inhibited from causing concave defects (pits) or scratches in this case also. In addition, since the surface to be polished of the glass substrate is protected by the additive, the fine abrasive particles and waste glass particles resulting from polishing are less apt to adhere to the surface and the amount of such substances to be adhered can be reduced. As a result, the glass substrate can be improved in surface smoothness and washability. Hydroxyl groups present on the surface of the fine abrasive particles interact with hydroxyl groups of the additive and this interaction makes the additive well compatible with the fine abrasive particles. It is thought that those effects of the additive are satisfactorily obtained because of such state of the additive. Consequently, the additive effectively functions especially when the fine abrasive particles are silica and the surface part to be polished is a glass comprising SiO₂ as the main component.

Pullulan is a saccharide formed by the polymerization of many monosaccharide molecules through glucoside bonds. Specifically, it is a polysaccharide formed by bonding three molecules of glucose through α-1,4 bonds to form maltotriose and bonding molecules of this saccharide through α-1,6 bonds. When this polysaccharide has a weight-average molecular weight in the range of from 10,000 to 1,000,000, high effects are obtained. When the weight-average molecular weight thereof is lower than 10,000, the effects are low. Even when the weight-average molecular weight thereof exceeds 1,000,000, the effects cannot be expected to be further heightened. Especially preferably, the weight-average molecular weight thereof is in the range of from 50,000 to 300,000. Weight-average molecular weight can be determined by gel permeation chromatography (GPC).

Examples of the alcohols include ethylene glycol, propylene glycol, diethylene glycol, and glycerol. Of these, ethylene glycol and glycerol are preferred from the standpoints of effects of addition, handleability, etc.

In the case where pullulan is added as the only additive to the polishing slurry, the content of pullulan in the polishing slurry is preferably 0.005-20% by mass, more preferably 0.02-10% by mass, especially preferably 0.1-2% by mass, from the standpoint of obtaining sufficient effects of the addition. If the content of pullulan is lower than 0.005% by mass, it is difficult for the pullulan to sufficiently surround the fine abrasive particles, resulting in reduced effects. In addition, the effect of inhibiting pit formation is also lessened. On the other hand, if the content thereof exceeds 20% by mass, the polishing slurry has an increased viscosity and this poses problems, for example, that the piping, filter, etc. through which the polishing slurry passes are clogged, that the high viscosity leads to a decrease in polishing rate, and that washability is poor and a residue of the polishing slurry remains after washing.

In the case where at least one of the alcohols is added as the only additive to the polishing slurry, the content of the alcohol in the polishing slurry is preferably 0.02-20% by mass, more preferably 0.5-10% by mass, especially preferably 1-5% by mass. If the content of the alcohol is lower than 0.02% by mass, the effect of preventing the abrasive material from drying is not sufficiently obtained or the effect of inhibiting pit formation is lessened. On the other hand, contents thereof exceeding 20% by mass are undesirable because the polishing slurry has an increased viscosity, as in the case of pullulan, and this poses problems, for example, that the piping, filter, etc. are clogged, that the high viscosity leads to a decrease in polishing rate, and that a residue of the polishing slurry remains after washing, i.e., the slurry has poor washability.

The contents of pullulan and the alcohol can be suitably determined within those ranges while taking account of polishing rate, uniformity of the polishing slurry, etc.

In the case where both pullulan and the alcohol are added to the polishing slurry, the contents of these vary depending on the proportion between these. Consequently, the contents thereof may be determined so as to obtain an optimal concentration according to the proportion between these while taking account of those ranges.

In the polishing slurry to be used in the invention, the water functions as a medium for dispersing the fine abrasive particles therein and dissolving the additive and other ingredients therein. It is therefore preferred to use pure water or ultrapure water from which foreign matters have been removed. If the water contains a foreign matter (fine particles) having a maximum diameter of 0.1 μm or larger, this foreign matter during polishing functions as a kind of abrasive material to cause surface defects such as scratches and pits to the surface being polished of the glass substrate. It is therefore difficult to attain high-quality polishing. Water has the function of slurrying with controlling the flowability of the polishing slurry. The content thereof is hence suitably determined according to polishing conditions, polishing properties, etc.

The polishing slurry to be used in the invention preferably contains an acid besides the abrasive material, water, and additive. This acid is incorporated in order to adjust the pH of the polishing slurry. Namely, the polishing slurry is adjusted so as to have a pH of preferably 0.5-4, more preferably 1-3, especially preferably 1.8-2.5, as stated above. The purpose of such pH adjustment of the polishing slurry is to obtain substantially the same effect as in conventional chemical polishing (acid polishing). Namely, by thus making the polishing slurry acidic, the surface of a glass substrate can be polished chemically and mechanically. Specifically, in mechanical polishing with an acid polishing slurry, convex parts of the glass surface are softened by the acid contained in the polishing slurry and can hence be easily removed by the mechanical polishing. As a result, not only the efficiency of polishing improves but also the glass particles or waste glass removed by the polishing can be prevented from newly forming mars because such glass particles have been softened. Consequently, the method of adjusting the pH of the polishing slurry to a value in an acid region in the invention is an especially effective method for efficiently polishing a glass substrate while attaining satisfactory smoothness. If the pH of the polishing slurry is lower than 0.5, the acidity is too high and this may pose a problem concerning polishing machine corrosion. On the other hand, pH values hereof higher than 4 are undesirable because the effect of chemically polishing glasses as described above decreases.

The pH adjustment of the polishing slurry in the invention can be conducted by using one acid or a combination of two or more acids selected from inorganic acids or organic acids. Examples of the inorganic acids include nitric acid, sulfuric acid, hydrochloric acid, perchloric acid, and phosphoric acid. Of these, nitric acid is preferred from the standpoint of handleability. Acids which highly corrode glasses, such as hydrofluoric acid, cannot be used because such acids make mars conspicuous. Examples of the organic acids include oxalic acid and citric acid.

For the purpose of adjusting the pH of the polishing slurry to a given value, a basic compound may be added besides an acid. As the basic compound, ammonia, potassium hydroxide, or a quaternary ammonium hydroxide such as tetramethylammonium hydroxide or tetraethylammonium hydroxide (hereinafter referred to as TEAH) can be used. In the case where absence of an alkali metal is desirable, ammonia is preferred.

Although the polishing slurry in the invention is generally used in the acid pH range of 0.5-4 as stated above, it is usable also in the pH range of 4-12. In this pH range also, the additive produces the same effects.

The polishing method of the invention is especially suitable as the finish polishing to be finally conducted when a glass substrate is polished through two or more polishing steps. It is therefore preferred that the glass substrate should be subjected beforehand to grinding to a given thickness and preliminary polishing for reducing the surface roughness thereof to or below a given value. This preliminary polishing may be conducted by one or more polishing steps in general use in this field. For example, two or more both-side lapping machines are successively disposed and a glass substrate is polished consecutively with these lapping machines while changing the abrasive material and polishing conditions, whereby the glass substrate can be preliminarily polished so as to have a given thickness and a given surface roughness. This surface roughness (Rms) to be attained by the preliminary polishing is, for example, preferably 3 nm or lower, more preferably 1.0 nm or lower, further preferably 0.5 nm or lower.

The glass substrate which has been polished by the polishing method of the invention is washed. By this washing, substances adherent to the polished surface of the glass substrate, such as the abrasive material, waste glass particles resulting from polishing, and other foreign matters, are removed to clean the glass substrate. In addition, the surface of the glass substrate can be neutralized by the washing. This washing therefore is an important step accompanying the polishing. If this washing is insufficient, not only defects are observed in a subsequent inspection, but also the quality required of the glass substrate cannot be obtained. Preferred examples of washing methods include a method in which the polished glass substrate is first washed with a hot aqueous solution of sulfuric acid and hydrogen peroxide, subsequently rinsed with water, and then washed with a solution of a neutral surfactant. However, methods of washing should not be construed as being limited thereto, and other methods may be used.

The polishing of a glass substrate in the invention is conducted while supplying the polishing slurry containing the additive to a polishing pad of a polishing apparatus. As the polishing apparatus, use can be made of a general polishing apparatus employed in this kind of polishing. For example, the glass substrate is sandwiched under a given load between polishing plates each having a polishing pad attached thereto. Alternatively, the glass substrate is bonded and fixed to a surface plate and the polishing pad of a polishing plate is pushed against the glass substrate. This glass substrate can be polished by rotating the polishing plate(s) (causing the polishing plate(s) to undergo revolution and rotation) on the glass substrate while supplying a given amount of the polishing slurry to the polishing pad(s). In this case, the amount of the polishing slurry to be supplied, polishing load, the speed of revolution or rotation of each polishing plate, etc. are suitably determined while taking account of the rate of polishing, accuracy of the finish of polishing, etc.

FIG. 3 illustrates a preferred polishing pad for use in the polishing method of the invention. This polishing pad is constituted of a supporting base 6 made of, e.g., a nonwoven fabric, sheet-form resin, or the like and a nap layer 7 attached thereto. The polishing pad is attached to a polishing plate of a polishing apparatus through the supporting base 6. Due to this attachment to a polishing plate through the supporting base 6, the polishing pad can be easily attached and removed. However, the nap layer 7 may be directly attached to a polishing plate.

This polishing pad having a nap layer 7 falls under suede pads. The thickness of the nap layer 7 varies depending on the material thereof, etc., and is not limited. However, the thickness thereof in suede pads is preferably about 0.3-1.0 mm from the standpoint of practical use. The material of the nap layer 7 preferably is a flexible resin foam having moderate elasticity. For example, resin foams of the ether, ester, or carbonate type or the like are preferred.

In the case where the polishing slurry described above is used to polish a glass substrate with the polishing pad, the nap layer 7 of the polishing pad preferably has a compressibility of 10% or higher, more preferably 15-60%, further preferably 30-60%. The compressive elastic modulus of the nap layer 7 is preferably 85% or higher, more preferably 90-100%, further preferabLy 95-100%. The terms compressibility and compressive elastic modulus herein mean the properties determined by the following examination methods.

A test sample of about 10 cm×10 cm is cut out of the nap layer of a suede pad. A Schopper type thickness meter is used to apply a pressure of 100 g/cm² to the test sample for 30 seconds through a pressing plane having a diameter of 1 cm and measure the thickness t₀ of the test sample after the 30-second pressing. Thereafter, a pressure of 1,120 g/cm² is applied to the same part of the test sample for 300 seconds and the thickness t₁ of the test sample after the 300-second pressing is measured. After this test sample is allowed to stand for 300 seconds without being pressed, a pressure of 100 g/cm² is applied to the same part of the test sample for 30 seconds and the thickness t₀′ of the test sample after the 30-second pressing is measured. The compressibility and compressive elastic modulus of the nap layer are determined from the t₀, t₁, and t₀′ using the following expressions 1 and 2.

Compressibility (%)=(t₀−t₁)/t₀×100 (1)

Compressive elastic modulus (%)=(t₀′−t₁)/(t₀−t₁)×100 (2)

If the compressibility of the nap layer is lower than 10%, the nap layer is rigid and difficult to deform and hence has the following drawback. At the time when the surface to be polished of a glass substrate is polished while supplying the polishing slurry, if fine abrasive particles having a large particle diameter coexist in the polishing slurry or if fine abrasive particles are nonuniformly distributed, the polishing pressure imposed on these particles is not dispersed but concentrated, which likely cause generation of concave defects. When a nap layer having a compressibility of 10% or higher is employed, those fine abrasive particles can be inhibited from forming concave defects. This is because when a polishing pressure is imposed on the fine abrasive particles, those parts of the nap layer which surround the fine abrasive particles deform elastically and thereby disperse and absorb the polishing pressure.

On the other hand, compressibilities of the nap layer exceeding 60% are undesirable because this nap layer during polishing is excessively compressed and deformed and this makes it difficult to polish uniformly and is apt to result in polishing nonuniformity. Namely, use of such nap layers leads to impaired flatness of the polished surface.

If the compressive elastic modulus of the nap layer is lower than 85%, the fine abrasive particles and the like having a large diameter which have been incorporated into the nap :Layer side from the polishing surface in contact with the glass substrate due to the elastic deformation of the flexible nap layer are apt to remain in the nap layer even after the relief of the polishing pressure because of the poor recovery properties of the nap layer. In addition, this nap layer is apt to locally come into contact with the glass substrate at a high pressure and, hence, the glass substrate is apt to develop concave defects. Furthermore, since the flatness of the polishing side of such a nap layer deteriorates with the continuation of polishing, the glass substrate thus polished also has impaired flatness. As long as the compressive elastic modulus of the nap layer is 85% or higher, the nap layer can be easily compressed and readily recovers. Because of this, fine abrasive particles having a large particle diameter and the like are less apt to remain in the layer and the pressure imposed on those fine abrasive particles incorporated in the layer can be satisfactorily dispersed. The generation of concave defects can hence be diminished or prevented. Thus, a glass substrate having excellent flatness and smoothness can be obtained.

Consequently, a polishing pad having a nap layer with a compressibility of 10% or higher and a compressive elastic modulus of 85% or higher is effective in the polishing method of the invention, which is intended especially to inhibit the generation of concave defects.

In the invention, the compressibility and compressive elastic modulus of the resin foam nap layer of the suede pad can be suitably adjusted by changing the kind of the resin, open pore diameter, porosity, density, foamed pore diameter, thickness, etc. In the case of a nap layer constituted of a uniform material, i.e., a nap layer whose material and properties are homogenous throughout the nap layer, the compressibility and compressive elastic modulus of this nap layer are even throughout the nap layer. However, in the case of a nap layer constituted of different materials superposed in the thickness direction, the compressibility and compressive elastic modulus of this nap layer mean those of the part which comes into contact with the glass substrate during polishing.

### Examples

The invention will be illustrated in greater detail by reference to the following Examples and Comparative Example.

### (1) Production of Glass Substrate Samples

An ingot of a synthetic quartz glass containing 7% by mass TiO₂ and produced by the flame hydrolysis method was cut into a platy shape having dimensions of 153 mm (width)×153 mm (length)×6.75 mm (thickness) with an inner-blade type slicer to produce sixty platy samples of the synthetic quartz glass (hereinafter referred to as “sample substrates”). Furthermore, these sample substrates were beveled with commercial diamond wheel so as to result in shape dimensions of 152 mm (width) by 152 mm (length) and a beveling width of 0.2-0.4 mm.

Subsequently, these sample substrates were preliminarily polished by the following method. Namely, a both-side lapping machine (manufactured by Speedfam Co., Ltd.) was used to first polish the main surfaces of the sample substrates until the thickness of each substrate reached 6.51 mm. Thereafter, these sample substrates were subjected to preliminary polishing with a both-side polishing machine (manufactured by Speedfam Co., Ltd.) so as to result in a surface roughness (Rms) of about 0.8 nm. The periphery of each sample substrate also was polished so that the edge faces were mirror-polished to a surface roughness (Ra) of 0.05 μm.

### (2) Preparation of Polishing Slurries

The polishing slurries of Examples 1 to 3 each were prepared by adding colloidal silica, additive(s), and an acid to water. The polishing slurry of Comparative Example 1 was prepared by adding colloidal silica and an acid to water without adding an additive. As the water, pure water was used. Nitric acid was used as the acid to adjust pH. Those polishing slurries were equal in the average primary-particle diameter and content of the colloidal silica; the average primary-particle diameter and the content were 10-20 nm and 20% by mass, respectively. The kind and content of the additive and the pH in each Example are shown in Table 1.

TABLE 1

| | Additive | | |
|---|---|---|---|
| | | Content | |
| | Kind | (mass %) | pH |
| Example 1 | pullulan | 0.5% | 2 |
| Example 2 | pullulan | 0.5% | 2 |
| | ethylene glycol | 1% | |
| Example 3 | ethylene glycol | 3% | 2 |
| Comparative | none | — | 2 |
| Example 1 | | | |

### (3) Polishing Conditions

Subsequently, the sixty sample substrates which had been preliminarily polished were divided into four groups which each were composed of fifteen substrates and were respectively for Examples 1 to 3 and Comparative Example 1. These groups were separately subjected to finish polishing using the following polishing apparatus under the following polishing conditions.
Polishing machine: both-side polishing machine
Polishing pad: suede pad

Compressibility: 20 (%)

Compressive elastic modulus: 95 (%)
Rotation speed of polishing plate: 35 rpm
Polishing load: 80 g/cm²
Polishing time: 50 minutes
Slurry flow rate: 10 L/min

### (4) Evaluation Method

After the sample substrates had been subjected to finish polishing under the conditions shown above, they were washed with a multistage automatic washing machine including a first tank which was a washing tank containing a surfactant solution and succeeding tanks constituted of a rinsing tank containing ultrapure water and a drying tank containing IPA. The sample substrates thus washed were inspected with a surface defect inspection apparatus for photomasks (manufactured by Lasertec Corp.) to count the number of concave defects having a half-value width of 60-150 nm in a 142 mm×142 mm area with respect to each of Examples 1 to 3 and Comparative Example 1. All the fifteen substrates were inspected in each of the Examples and Comparative Example. The total numbers of defects were compared, with the number of defects counted in Comparative Example 1 being taken as 1. The results obtained are shown in Table 2.

An explanation is given on a concave defect having a half-value width of 60-150 nm by reference to a drawing.

FIG. 2 is a diagrammatic enlarged sectional view of a concave defect. In general, a concave defect 5 formed in a glass substrate 1 is a concave part having an approximately hemispherical shape and, hence, the cross-section shape thereof is nearly circular. An approximate circle is hence obtained from the cross-section shape of the concave defect 5, and a parabolic curve p is determined from the diameter w of the approximate circle and the depth d of the concave defect 5. When the points of intersection of this parabolic curve p and a straight line t drawn along a depth of d/2 are expressed by a and b, then the half-value width r of the concave defect 5 can be obtained as the distance between a and b. Consequently, the characterization of the concave defect 5 by its size in terms of half-value width r by the method described above can reflect the planar direction size and depth direction shape of the concave defect 5. If the half-value width r exceeds 60 nm, the concave defect 5 exerts a greater influence when the glass substrate is used as a mask for exposure, resulting in a possibility that a phase defect might appear. On the other hand, concave defects larger than 150 nm in half-value width r are not allowable in glass substrates for use as exposure masks. Consequently, the sample substrates were evaluated for concave defects having a half-value width of 60-150 nm.

Furthermore, the surface roughness Rms of each sample substrate was determined with an atomic force microscope (manufactured by Seiko Instruments Inc.). This examination for surface roughness was made on an arbitrarily selected one area (10 μm×10 μm area) in each sample substrate, and an average for the fifteen substrates was calculated. The results obtained are also shown in Table 2.

TABLE 2

| | | | | Comparative |
|---|---|---|---|---|
| | Example 1 | Example 2 | Example 3 | Example 1 |
| Concave defect | 0.6 | 0.4 | 0.7 | 1 |
| Surface roughness | 0.090 | 0.078 | 0.070 | 0.085 |
| Rms (nm) | | | | |

It can be seen from Table 2 that the numbers of concave defects in Examples 1 to 3, in which the additive(s) had been added to the polishing slurry, were smaller by 30-60% than that in Comparative Example 1, in which no additive had been added. It can also been seen that Examples 2 to 3 were improved also in surface roughness as compared with Comparative Example 1. Incidentally, concave defects larger than 150 nm were detected in Comparative Example 1 in an average number of 0.2, whereas no such large concave defects were observed in Examples 1 to 3.

While the present invention has been described in detail and with reference to specific embodiments thereof, it will be apparent to one skilled in the art that various changes and modifications can be made therein without departing from the spirit and scope thereof.

This application is based on Japanese Patent Application No. 2007-156890 filed on Jun. 13, 2007, and the contents thereof are herein incorporated by reference.

### INDUSTRIAL APPLICABILITY

The invention can polish a glass substrate so as to give a high-quality surface reduced especially in concave defects. The invention is hence suitable for the polishing of a glass substrate for use as a mask blank in an exposure tool for producing high-precision semiconductor devices having a high degree of integration.

1. A method of polishing a glass substrate which comprises polishing the glass substrate with a polishing pad while supplying a polishing slurry comprising an abrasive material and water to the polishing pad,
wherein the polishing slurry contains at least one member selected from the group consisting of pullulan and water-soluble alcohols which are polyvalent organic compounds having two or more OH groups.

2. The method of polishing a glass substrate of claim 1, wherein the polishing slurry contains at least one water-soluble alcohol which is a polyvalent organic compound having two or more OH groups.

3. The method of polishing a glass substrate of claim 2, wherein the content of the water-soluble alcohol which is a polyvalent organic compound having two or more OH groups in the polishing slurry is 0.02-20% by mass.

4. The method of polishing a glass substrate of claim 1, wherein the abrasive material is fine particles of silica having an average primary-particle diameter of 80 nm or smaller.

5. The method of polishing a glass substrate of claim 4, wherein the silica is colloidal silica.

6. The method of polishing a glass substrate of claim 1, wherein the polishing slurry has a pH of 0.5-4.

7. The method of polishing a glass substrate of claim 1, wherein the surface of the glass substrate which is to be polished has been preliminarily polished.

8. The method of polishing a glass substrate of claim 1, wherein the polishing pad has a nap layer having a compressibility of 10% or higher and a compressive elastic modulus of 85% or higher.

9. The method of polishing a glass substrate of claim 1, wherein the glass substrate is a glass substrate for mask blank use.
